(19) United States
(12) Patent Application Publication
(10) Pub. No.: US 2020/0133331 A1
(43) Pub. Date: Apr. 30, 2020

(54) ELECTRONIC DEVICES WITH INTEGRATED DISPLAY SCREENS

(71) Applicant: Hewlett-Packard Development Company, L.P., Spring, TX (US)

(72) Inventors: Sara R Ferris, Houston, TX (US); Dimitre D Mehandjiysky, Spring, TX (US); Kevin L Massaro, Spring, TX (US)

(21) Appl. No.: 16/607,348

(22) PCT Filed: Apr. 28, 2017
(86) PCT No.: PCT/US2017/030211

§ 371 Date: Oct. 22, 2019

(51) Int. Cl. G06F 1/16; H05K 5/00; H05K 5/02; G06F 3/041

(52) U.S. Cl. CPC G06F 1/1601; H05K 5/0017; H05K 5/0247; G06F 2203/04108; G06F 3/041; G06F 2200/1631; G06F 2200/1612; H05K 5/0217

(57) ABSTRACT

An electronic device is described having a support base including a base front surface, a normal vector perpendicular to at least a portion of the base front surface, and a horizontally elongate slot extending through a plane that is perpendicular to the normal vector. The device also includes a first display screen supported by the support base. The base front surface, the plane, and the first display screen face a common direction.

### BACKGROUND

Computers and user interfaces for computers are developed and modified to achieve a functional purpose, convenience, or an ergonomic benefit. For example, an all-in-one computer combines a computer processor, a memory, and a display screen in a single unit. User interfaces such as keyboards and pointing devices (e.g., a mouse, a trackball, a game controller, or a touch tablet surface) may be attached or removed as needed.

### BRIEF DESCRIPTION OF THE DRAWINGS

Various examples will be described below referring to the following figures:

FIG. 1 is an electronic display device in accordance with various examples;

FIG. 2 is a side view in partially schematic form of the electronic display device of FIG. 1 in accordance with various examples;

FIG. 3 is a block diagram of the electronic display device of FIG. 1 including a processor and processor-accessible storage in accordance with various examples;

FIG. 4 is a close, front view in partially schematic form of the electronic display device of FIG. 1 in accordance with various examples;

FIG. 5 is a close, front view in partially schematic form of an electronic display device in accordance with various examples;

FIG. 6 is a close, front view in partially schematic form of an electronic display device in accordance with various examples; and

FIG. 7 is a method in accordance with various examples.

### DETAILED DESCRIPTION

As used herein, including in the claims, the word “or” is used in an inclusive manner. For example, “A or B” means any of the following: “A” alone, “B” alone, or both “A” and “B.” In addition, when used herein including the claims, the word “generally” or “substantially” means within a range of plus or minus 20%.

An electronic display device in accordance with various examples includes a support base, a first display screen supported by the support base, and a touch-sensitive display screen to slide out from and into a front surface of the support base for deployment and stowage. The touch-sensitive display screen may be described as a deployable screen or a deployable touch screen. The deployable screen may be dimensionally stable, maintaining substantially the same shape when deployed for use and when stowed, as will be described below. In some examples, the deployable screen is slidingly disposed on a rail that extends within the support base. In various examples, the first display screen faces in a horizontal direction. Alternatively, the first display screen may be tilted away from horizontal. The deployable screen may be arranged to lie horizontally along a table, a traditional desktop, another working surface, or a rail when deployed for use, the deployable screen facing vertically. Other orientations of the deployable screen may be implemented. The front surface of the support base and the first display screen face in a common direction.

Multiple options are available for transferring data between a computer and the deployable screen, including a multi-conductor ribbon cable, another type of multi-conductor cable or cord, and wireless communication, as examples. The wireless communication may include Wi-Fi®, Bluetooth®, or near field communications (NFC) protocols, as examples. Likewise, multiple options are available for providing power to the deployable screen, including as examples, conductors within the ribbon cable, an electrical cord, electrical contact through the rail or through electrodes on the rail, and wireless charging. Some examples include a processor and storage accessible by the processor, both housed within the support base and forming a computer system. An example is a deployable screen integrated into an all-in-one (AIO) desktop personal computer. The processor-accessible storage may include instructions that, when executed, cause the processor to interact with the first display screen and the deployable screen, causing this pair of display screens to share information that may be received from a user or to share information that may be displayed to the user.

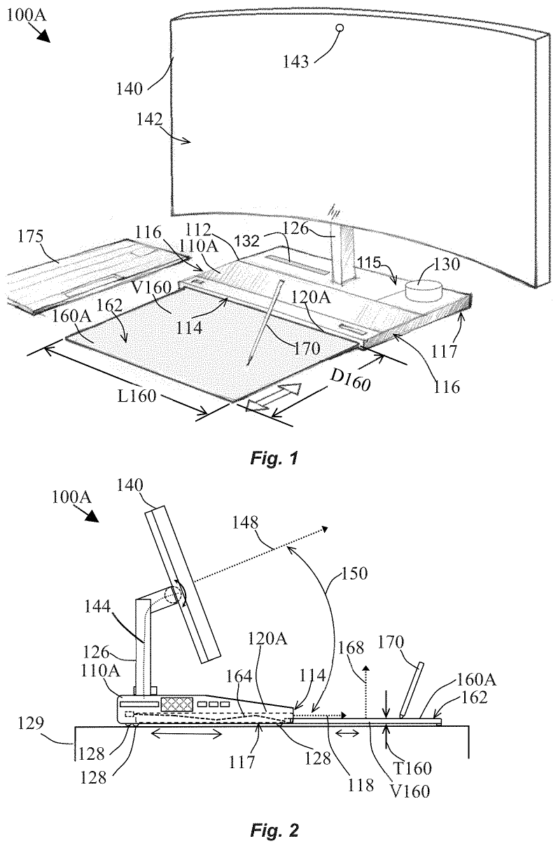

An example of an electronic display device 100A in accordance with the principles disclosed herein is shown in FIG. 1. As shown in FIG. 1, electronic display device 100A may include a support base 110A, a first display screen 140 supported from base 110A, and a second display screen 160A that is deployable or extendable from base 110A, which are coupled together as a single unit. In this example, the electronic display device 100A may be an AIO computer. A separate keyboard 175 may be coupled to device 100A.

Referring now to FIG. 1 and FIG. 2, support base 110A may include a body 112 having a base front surface 114, an upper surface 115, side surfaces 116, and a bottom surface 117. Base front surface 114 may be characterized by a normal vector 118 that is perpendicular to at least a portion of base front surface 114. In this example, a majority of base front surface 114 is flat, and normal vector 118 may be perpendicular to the center or perpendicular to a central region of base front surface 114 and to a majority of base front surface 114. It is anticipated that base front surface 114 may typically be positioned so that normal vector 118 points toward a location where a user is likely to be while using electronic display device 100A. The direction of normal vector 118 will be referred to herein as the front or forward direction. A slot 120A (FIG. 1) may extend through a plane that may be perpendicular to normal vector 118 and may include a portion of base front surface 114, or slot 120A may extend through base front surface 114, into base 110A. On base front surface 114, slot 120A may be horizontally elongate as compared to its height, extending lengthwise between sides 116. In depth, slot 120A may extend sufficiently into base body 112 to slidingly receive all or a majority of a deployable, second display screen 160A inside base body 112. A mounting arm 126 extends upward from base 110A and couples to first display screen 140. Arm 126 may allow first display screen 140 to swivel about a vertical axis or to tilt about a horizontal axis, as examples, relative to base 110A.

As shown in FIG. 2, support base 110A may also include multiple, cylindrically-shaped, tensioned rollers 128 extending below bottom surface 117 to rest on top of a desk surface 129, a table surface, or any other suitable working surface. Rollers 128 may allow base 110A to roll linearly along desk surface 129 when pulled or pushed by a user who applies a sufficient force. Rollers 128 may resist movement that might otherwise be caused by a slanted desk surface, accidental bumps, or other unintentional factors. Rollers 128 may also be called torqued rollers. Rollers 128 may vary in shape, size, and quantity or position and may be replaced by tensioned wheels or roller balls, as examples. In various examples, rollers 128 are replaced by pads that resist movement such as rubber or elastomeric pads or are replaced by pads that allow movement, such as felt pads. Rollers 128 may also be replaced by a static “foot” member extending downward from base 110A, or instead, base 110A may rest directly on a desk surface or another surface.

Referring again to FIG. 1 and FIG. 2, support base 110A may incorporate a jog wheel 130 that is coupled for rotational movement about the vertical axis and may be communicably coupled with wires or electronics in base 110A to transmit rotational movement or position. Jog wheel 130 may be a user input device, allowing a user to move a cursor on a display screen 140, 160A (i.e., first display screen 140, second display screen 160A, or both display screens 140, 160A). For example, by using wheel 130, a user may choose from a list of options that are displayed at various times. Base 110A may also include wireless charging equipment 132 capable of providing power to charge a battery of one or more peripheral devices that may interact with electronic display device 100A or capable of charging a battery of a portable communication device.

First display screen 140 includes a display surface 142, which is curved in this example, and a camera 143. First display screen 140 may be coupled for data communication with base 110A, with second display screen 160A, or with a processor that controls display screens 140, 160A. In FIG. 2, a data communication coupling 144 extends from first display screen 140 into base 110A. In general, coupling 144 may include a cable or wireless equipment. Display surface 142 may be characterized by a normal vector 148 that is perpendicular to at least a portion of surface 142. In this example, vector 148 is perpendicular to the center of surface 142. It is anticipated that first display screen 140 will typically be positioned so that normal vector 148 (and, therefore, surface 142) points toward the location where a user is likely to be while using electronic display device 100A. Thus, base front surface 114 and first display screen 140 face a common direction. In this example, the common direction is toward the location where a user is likely to be while using electronic display device 100A. Within this definition of common direction, first display screen 140 may be adjusted so that normal vector 148 points toward the location where a user's face is likely to be while normal vector 118 may point toward a user's body, separating vectors 118, 148 by a non-zero angle 150. Angle 150 measures the angular displacement of vectors 118, 148. If normal vector 118 is considered to point in a forward direction, vector 148 may point forward; may point left, right, up, or down; or may point a combination of left or right and up or down, as examples. In some examples, angle 150 may range between +/−45 degrees in any of the directions mentioned, describing a range for the common direction. In some examples, angle 150 may range between +/−85 degrees in any of the directions mentioned, describing a range for the common direction. In some of these instances, angle 150 will be zero and vectors 118, 148 will be parallel. These possible ranges for angle 150 do not prohibit first display screen 140, in at least some examples, from alternatively pointing upward, fully to the left, or fully to the right (e.g., angle 150 would be 90 degrees), or possibly backwards (angle 150 greater than 90 degrees), but in any of these alternate conditions, first display screen 140 and base front surface 114 may not be pointing in a common direction.

Continuing to reference FIG. 1 and FIG. 2, second display screen 160A may include a display surface 162 and a data communication coupling, which in this example comprises an electrically conductive cable, ribbon cable 164. Display surface 162 may be characterized by a normal vector 168 that is perpendicular to at least a portion of surface 162. In this example, surface 162 is flat, and normal vector 168 is perpendicular to the center of surface 162 and perpendicular to all of surface 162. Surface 162 faces upward and normal vector 168 is perpendicular or generally perpendicular to normal vector 118, extending from base front surface 114. Ribbon cable 164 may extend between and may provide electrical power and data transfer between second display screen 160A and support base 110A or components coupled to base 110A. Second display screen 160A may be integrated with the support base 110A and may slide out from and into slot 120A. A mechanism may be included to eject second display screen 160A from support base 110A or to latch second display screen 160A within support base 110A until a user attempts to deploy second display screen 160A. For example, a motorized or smooth eject mechanism may be used.

Second display screen 160A occupies a volume V160 having a length L160, a depth D160, and a thickness or height T160. These dimensions of volume V160 may not change substantially when second display screen 160A is slid out from or into slot 120A. In some examples, second display screen 160A is rigid. In some examples, second display screen 160A is flexible, and each of the dimensions of volume V160 may change by up to 5% when second display screen 160A is slid out from or into slot 120A. In some examples, each of these dimensions of volume V160 may change by up to 10%. For any of these examples having volume V160 as described, second display screen 160A is dimensionally stable, maintaining substantially the same shape when deployed for use and when stowed, and second display screen 160A does not “roll up” (e.g., wrap around an axis) when slid out from or into slot 120A. Even so, in some examples, these dimensions of volume V160 may change by more than 10% when second display screen 160A is slid out from or into slot 120A, and in some of these examples, display screen 160C may roll up. Such examples in which the display screen 160C rolls up may omit rails 190A.

Second display screen 160A may be touch-sensitive, capable of sensing at least one of human contact, human proximity, a passive stylus, and an active stylus. An active stylus or pen 170 is shown and may be charged at charging equipment 132.

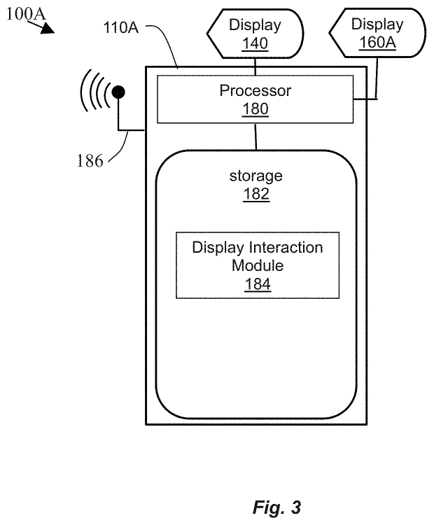

Referring to FIG. 3, within support base 110A, electronic display device 100A may include a processor 180 communicatively coupled to non-transitory machine-readable storage 182. Storage 182 may include an electronic, magnetic, optical, or other physical storage device that stores executable instructions. Thus, storage 182 may comprise, as examples, Read Only Memory (ROM), an Electrically-Erasable Programmable Read-Only Memory (EEPROM), a storage drive, an optical disc, and the like. Storage 182 may include or store executable instructions in a display interaction module 184 which, when executed, cause the processor 180 to interact with display screens 140, 160A. For example, module 184 may include instructions to display information for a user and to display information that may be received from a user. The information may be displayed on either or both display screens 140, 160A. Module 184 may include machine instructions to cause processor 180 to receive the information via second display screen 160A and to display the information on at least one of the first display screen 140 and the second display screen 160A. Support base may also include wireless equipment 186 for communication, such as Wi-Fi®, Bluetooth®, or near field communications (NFC) protocols, as examples.

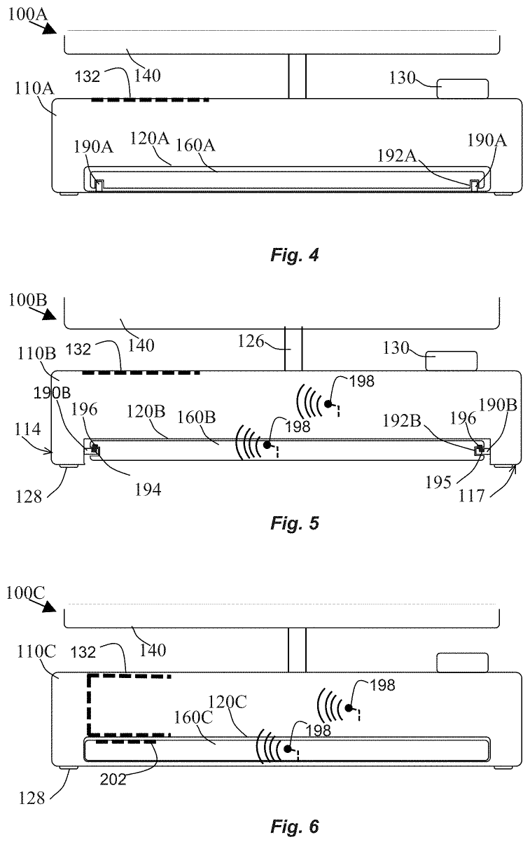

FIG. 4 shows a close, front view of electronic display device 100A showing second display screen 160A retracted into base 110A. A pair of rails 190A may be coupled or mounted along the bottom of slot 120A, one on either side, extending lengthwise into the depth of slot 120A. Each side of second display screen 160A may include a groove 192A extending upward through the bottom of second display screen 160A and extending lengthwise along all or a portion of the screen's depth. Second display screen 160A may be disposed on rails 190A using the grooves 192A, and the second display screen 160A thus slides along these rails. Rails 190A may be fixed in length such that much or all of second display screen 160A can be pulled beyond rails 190A when deployed for use. Alternately, each rail 190A may have two more elongate members coupled by wheels allowing the rail to extend with second display screen 160A as it deploys outward for use. In various examples, second display screen 160A can be coupled to rails 190A or another part of base 110A such that second display screen 160A does not fully separate from base 110A, or second display screen 160A may be fully removable from base 110A when deployed. Alternatively, second display screen 160A may be disposed to slide along rails 190A without grooves 192A.

FIG. 5 shows another example of an electronic display device in accordance with the principles disclosed herein. Electronic display device 100B may include many of the same features and options as electronic display device 100A. Similar to device 100A, device 100B may include a support base 110B, a first display screen 140 supported from base 110B, and a second display screen 160B that is deployable or extendable from base 110B.

Support base 110B may include many of the same features and options as support base 110A. Support base 110B may include a slot 120B extending through a plane that may be perpendicular to normal vector 118 and may include a portion of base front surface 114, or slot 120A may extend through base front surface 114. On base front surface 114, slot 120B is horizontally elongate as compared to its height. In depth, slot 120B extends sufficiently to receive all or a majority of second display screen 160B. Differing from slot 120A, slot 120B extends down through bottom surface 117, between tensioned rollers 128. Alternatively, slot 120B may be replaced by slot 120A. A pair of rails 190B may be mounted along opposite sides of slot 120B, extending depthwise into the depth of slot 120B. One rail 190B may provide a positive electrode 194, and the other rail 190B may provide a neutral, negative, or ground electrode 195. Electrodes 194, 195 may extend along all or a portion of the length of rails 190B. The electrodes 194 and 195 may power the second display screen 160B, as described below. The possibilities for the lengths of rails 190B may be like the possibilities described above for rails 190A.

Second display screen 160B may include many of the same features and options as second display screen 160A. For example, second display screen 160B in FIG. 6 may be dimensionally stable and may not roll up when slid out from or into slot 120B. Even so, in some examples, the volume occupied by second display screen 160B may change by more than 10% when second display screen 160B is slid out from or into slot 120B. Each side of display screen 160B may include a groove 192B, extending horizontally through the side surface and extending lengthwise along all or a portion of the screen's depth. Within grooves 192B, second display screen 160B may be disposed on rails 190B to slide along these rails. Electrical brushes 196 may couple to second display screen 160B in the vicinity of each groove 192B to maintain electrical contact with electrodes 194, 195, providing an electrical path through which electrical power may be provided to second display screen 160B. When slid out from support base 110B, second display screen 160B may face upward and remain in contact with the electrodes 194, 195. Wireless equipment 198 (e.g., Bluetooth, Wi-Fi®, or near field communications (NFC) protocols) may provide a data communication coupling between second display screen 160B and base 110B or equipment in base 110B. Thus, instead of an electrically conductive cable to communicate data and power, as in electronic display device 100A, electronic display device 100B may transmit power to second display screen 160B through rails that couple it to the support base and may exchange data with second display screen 160B through wireless equipment.

FIG. 6 shows still another example of an electronic display device in accordance with the principles disclosed herein. Electronic display device 100C may include many of the same features and options as electronic display device 100A. Similar to electronic display device 100A, device 100C may include a support base 110C, a first display screen 140 supported from base 110C, and a second display screen 160C that may be deployable or extendable from within base 110C.

Support base 110C may include many of the same features and options as support base 110A. In regard to similarity, support base 110C may include a horizontally elongate slot 120C extending through a plane that may be perpendicular to normal vector 118 and may include a portion of base front surface 114, or slot 120A may extend through base front surface 114. In depth, slot 120C may extend sufficiently into base 110C to receive all or a majority of second display screen 160C. Differing from base 110A of FIG. 3, base 110C of FIG. 6 may lack rails 190A.

Second display screen 160C may include many of the same features and options as second display screen 160A. For example, second display screen 160C in FIG. 6 may be dimensionally stable and may not roll up when slid out from or into slot 120C. Even so, in some examples, the volume occupied by second display screen 160C may change by more than 10% when second display screen 160C is slid out from or into slot 120C, and in some of these examples, second display screen 160C may roll up. Differing from FIG. 3, second display screen 160C of FIG. 6 may lack grooves to receive rails. Like second display screen 160B, wireless equipment 198 may provide a data communication coupling between second display screen 160C and base 110C or equipment in base 110C. Second display screen 160C may include wireless charging equipment 202 to receive power from wireless charging equipment 132 or another piece of wireless charging equipment in base 110C. The wireless charging equipment 132, 202 may contact each other or may be adjacent each other when recharging a battery to provide or store power for second display screen 160C. Thus, display screen 160C may in some examples be wirelessly coupled to base 110C for electrical power and data communication and may be removed and separated from base 110C when deployed for use. Electronic display device 100C, when configured as described, may lack physical, wired connections between screen 160C and base 110C. Alternatively, second display screen 160C may include a docking plug, and base 110C may include a docking receptacle to charge a battery of second display screen 160C when stored within base 110C.

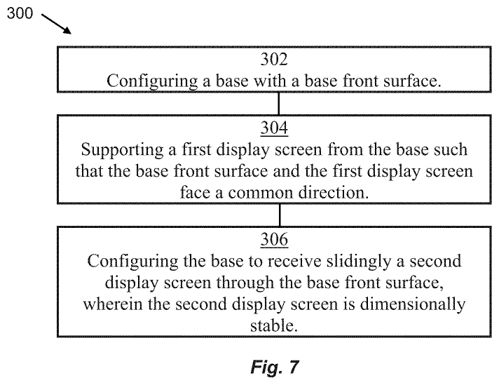

Referring to FIG. 7, an example method 300 is shown for implementing the electronic display devices such as those disclosed herein. For convenience, the operations shown in FIG. 7 are described below with reference also to FIG. 1 through FIG. 4 but are applicable to the other examples as well, in accordance with the principles described herein.

At 302, method 300 includes configuring a base with a base front surface. At 304, method 300 includes supporting a first display screen from the base such that the base front surface and the first display screen face a common direction. As an example, first display screen 140 and base front surface 114 of base 110A face a common direction, as described above. At 306, method 300 includes configuring the base to receive slidingly a second display screen through the base front surface. First display screen 140 may be received slidingly into or deployed through slot 120A in the base front surface 114. The second display screen may be dimensionally stable.

In some instances, method 300 may include coupling the second display screen to the support base for power transmission by a wired connection. Method 300 may include coupling the second display screen to the support base for data exchange by another wired connection. An example is the connection of a first conductor or set of conductors of a ribbon cable 164 for power transmission and the connection of a second conductor or set of conductors within the same cable for data transmission, as was described of the electrical connections between first display screen 140 and the support base 110A. A cable other than a ribbon cable or multiple, physically separate cables may also be used. Various implementations of method 300 may include fewer operations than described, and other implementations of method 300 may include additional operations.

The above discussion is meant to be illustrative of the principles and various examples of the present disclosure. Numerous variations and modifications will become apparent to those skilled in the art once the above disclosure is fully appreciated. It is intended that the following claims be interpreted to embrace all such variations and modifications. For example, although various examples of the electronic display devices disclosed may be implemented in AIO computers, the concepts described herein may also be applied to other electronic display devices, such as stand-alone monitors and laptop computers. In general, the second display screen may include or exclude touch sensitivity. In some examples, camera 143 may view or interact with display surface 162 of second display screens 160A, B, and/or C to facilitate user input like a touch-sensitive surface. In some examples, the second display screen is passive, and a projector disposed on first display screen 140, for example, may project an image on the second display screen, and camera 143 may facilitate user input on the second display screen.

In addition to the modes or equipment for transmitting power and data between a support base and a second screen that were described above, other modes or equipment and combinations thereof are possible. Although electrodes 194, 195 and brushes 196 were discussed in the context of electronic display device 100B that may include rails inside a slot, a similar device may include electrodes or brushes for power transmission to a second display screen disposed in a slot that lacks rails. In some examples, a second display screen may be disposed in a slot that extends below the bottom surface of a base body 112 of a support base. Such a slot may extend through a plane that may be perpendicular to normal vector 118 and may include a portion of base front surface 114, or the slot may extend through base front surface 114. Referring to FIG. 1 and FIG. 2 for convenience, although first display screen 140 was shown disposed on a single mounting arm 126 that may remain vertical, first display screen 140 may be mounted on a pair of hinge arms extending from the sides of first display screen 140 or from the sides of support base 110A, B, and/or C. The hinge arms may allow first display screen 140 to swing relative to the hinge arms or relative to the support base, swinging in a plane that includes normal vector 118.

What is claimed is:

1. An electronic device comprising:
a support base including a base front surface, a normal vector perpendicular to at least a portion of the base front surface, and a horizontally elongate slot extending through a plane that is perpendicular to the normal vector;
a first display screen supported by the support base; and
a dimensionally stable second display screen integrated with the support base, wherein the second display screen is to slide out from and into the slot in the support base,
wherein the base front surface, the plane, and the first display screen face a common direction.

2. An electronic device in accordance with claim 1 including a rail extending within the support base, toward the slot,
wherein the second display screen is disposed on the rail to slide along the rail.

3. An electronic device in accordance with claim 2 wherein the rail includes an electrode to transfer electrical power from the support base to the second display screen; and
wherein, when slid out from the support base, the second display screen remains in contact with the electrode and faces upward.

4. An electronic device in accordance with claim 1 comprising a processor and storage accessible by the processor and storing executable machine instructions,
wherein the processor and the storage are contained within the support base; and
wherein, when executed, the machine instructions cause the processor to cause the first display screen and the second display screen to display information that is received from a user.

5. An electronic device in accordance with claim 4 wherein, when executed, the machine instructions cause the processor to receive the information via the second display screen and to display the information on at least one of the first display screen and the second display screen.

6. An electronic device in accordance with claim 1 wherein the support base comprises a bottom surface and a plurality of tensioned rollers extending below the bottom surface.

7. An electronic device in accordance with claim 1 wherein the second display screen is touch-sensitive to at least one of human contact, human proximity, a passive stylus, and an active stylus.

8. An electronic device comprising:
a support base with a base front surface;
a first display screen supported from the support base such that the base front surface and the first display screen face a common direction; and
a second display screen,
wherein the support base is to receive slidingly the second display screen through the base front surface;
wherein the second display screen is dimensionally stable.

9. An electronic device in accordance with claim 8 wherein the second display screen is coupled to the support base for power transmission by a wired connection; and
wherein the second display screen is coupled to the support base for data exchange by another wired connection.

10. A computer system comprising:
a support base including a base front surface and a horizontally elongate slot extending through the base front surface;
a processor and storage accessible by the processor, the processor and the storage housed within the support base;
a first display screen having a data communication coupling that extends to the support base; and
a rigid second display screen integrated with the support base, wherein the second display screen is to slide out from and into the slot in the support base,
wherein the base front surface and the first display screen face a common direction.

11. A computer system in accordance with claim 10 wherein the storage is storing executable machine instructions;
wherein, when executed, the machine instructions cause the processor to cause the first display screen and the second display screen to display information that is received from a user.

12. A computer system in accordance with claim 11 wherein the first display screen is mounted to the support base for support.

13. A computer in accordance with claim 10 comprising a rail coupled to the support base;
wherein the second display screen is slidingly disposed on the rail.

14. A computer system in accordance with claim 10 wherein an electrically conductive cable extends between the support base and the second display screen to transfer data therebetween.

15. A computer system in accordance with claim 10 wherein the second display screen is communicably coupled to the support base by wireless equipment to transfer data therebetween.
